(19) United States
(12) Patent Application Publication
(10) Pub. No.: US 2025/0221028 A1
(43) Pub. Date: Jul. 3, 2025

(54) SELECTIVELY MERGED GATES IN STACKED FETS

(71) Applicant: INTERNATIONAL BUSINESS MACHINES CORPORATION, Armonk, NY (US)

(72) Inventors: Shay Reboh, Guilderland, NY (US); Albert M. Chu, Nashua, NH (US); Junli Wang, Slingerlands, NY (US); Ruilong Xie, Niskayuna, NY (US)

(21) Appl. No.: 18/398,731

(22) Filed: Dec. 28, 2023

(51) Int. Cl. H01L 27/092; H01L 21/822; H01L 21/8238; H01L 29/06; H01L 29/417; H01L 29/423; H01L 29/66; H01L 29/775

(52) U.S. Cl. CPC H10D 84/856; H10D 30/014; H10D 30/43; H10D 30/6729; H10D 30/6735; H10D 62/121; H10D 84/0186; H10D 84/038; H10D 88/01

(57) ABSTRACT

Semiconductor devices and methods of forming the same include a bottom transistor having a bottom gate. A top transistor has a top gate above the bottom gate and is separated from the bottom transistor by a dielectric layer. A conductive via extends through the top gate and the dielectric layer to contact the bottom transistor. A dielectric liner between the conductive via and the top gate electrically insulates the top gate from the conductive via.

### BACKGROUND

The present invention generally relates to semiconductor device fabrication and, more particularly, to devices having stacked field effect transistors (FETs).

Stacking FETs is a way to improve the density of transistors in a given device. By arranging transistors vertically, particularly those which benefit from proximity to one another, the area of complex layouts may be reduced and more transistors can be fit onto a single device. For example, complementary metal-oxide-semiconductor (CMOS) devices may include pairs of transistors, with one transistor of a pair having a first polarity (e.g., p-type) and with the other transistor of the pair having a second polarity (e.g., n-type). By stacking such FETs, the devices may be connected directly to one another.

In some cases, a single layout may call for some stacked FETs that have merged gates and some stacked FETs that have separated gates. Each is useful for different purposes. For example, merged gates may be used for a CMOS stack, while separated gates may be used for a stack that implements a cross-couple. Implementing both types on a single device may involve complex fabrication processes, adding to the cost and lowering the yield.

### SUMMARY

A semiconductor device includes a bottom transistor having a bottom gate. A top transistor has a top gate above the bottom gate and is separated from the bottom transistor by a dielectric layer. A conductive via extends through the top gate and the dielectric layer to contact the bottom transistor. A dielectric liner between the conductive via and the top gate electrically insulates the top gate from the conductive via.

A semiconductor device includes separated-gate transistors and merged-gate transistors. The separated-gate transistors include a first bottom transistor having a first bottom gate, a first top transistor having a first top gate above the first bottom gate, separated from the first bottom transistor by a dielectric layer, a first conductive via that extends through the top gate and the dielectric layer to contact the bottom transistor, and a dielectric liner between the first conductive via and the first top gate that electrically insulates the first top gate from the first conductive via. The merged-gate transistors include a second bottom transistor having a second bottom gate, a second top transistor having a second top gate above the second bottom gate, separated from the second bottom transistor by the dielectric layer, and a second conductive via that extends through the second top gate and the dielectric layer to contact the second bottom gate, making electrical contact to the second top gate and to the second bottom gate.

A method of forming a semiconductor device includes forming a first bottom FET having a first bottom gate. A first top FET having a first top gate is formed over the first bottom gate. A first via is etched through the first top gate to expose the first bottom gate. A dielectric liner is formed in the first via. Conductive material is deposited to fill the first via with conductive material that is electrically insulated from the first top gate by the dielectric liner.

These and other features and advantages will become apparent from the following detailed description of illustrative embodiments thereof, which is to be read in connection with the accompanying drawings.

### BRIEF DESCRIPTION OF THE DRAWINGS

The following description will provide details of preferred embodiments with reference to the following figures wherein:

FIG. 1 is a layout view of a semiconductor device having stacked field effect transistors (FETs), including a conductive via that passes through a gate of a top FET to reach a gate of a bottom FET, in accordance with an embodiment of the present invention;

FIG. 2 is a set of cross-sectional views of a step in the fabrication of a semiconductor device with stacked FETs with optional gate merging, showing a top FET and a bottom FET, in accordance with an embodiment of the present invention;

FIG. 3 is a set of cross-sectional views of a step in the fabrication of a semiconductor device with stacked FETs with optional gate merging, the formation of a via through a gate of the top FET, in accordance with an embodiment of the present invention;

FIG. 4 is a set of cross-sectional views of a step in the fabrication of a semiconductor device with stacked FETs with optional gate merging, the deposition of a dielectric layer on inner surfaces of the via, in accordance with an embodiment of the present invention;

FIG. 5 is a set of cross-sectional views of a step in the fabrication of a semiconductor device with stacked FETs with optional gate merging, showing an anisotropic etch of the dielectric layer to remove material from horizontal surfaces, in accordance with an embodiment of the present invention;

FIG. 6 is a set of cross-sectional views of a step in the fabrication of a semiconductor device with stacked FETs with optional gate merging, showing the deposition of conductive material to fill the via, in accordance with an embodiment of the present invention;

FIG. 7 is a set of cross-sectional views of a step in the fabrication of a semiconductor device with stacked FETs with optional gate merging, the removal of conductive material from above the gate of the top FET, in accordance with an embodiment of the present invention;

FIG. 8 is a set of cross-sectional views of a step in the fabrication of a semiconductor device with stacked FETs with optional gate merging, showing the formation of separated gate contacts to the gate of the top FET and to the conductive via, in accordance with an embodiment of the present invention;

FIG. 9 is a set of cross-sectional views of a set of stacked FETs with merged gates, showing a conductive FET, in accordance with an embodiment of the present invention;

FIG. 10 is a block/flow diagram of a method for forming a semiconductor device with stacked FETs with optional gate merging, in accordance with an embodiment of the present invention.

### DETAILED DESCRIPTION

Devices with stacked field effect transistors (FETs) can be formed with a process that creates multiple stacked FETs and then selectively determines which will have merged gates and which will have separated gates, thereby decreasing the cost and complexity of the fabrication process. To accomplish this, a via may be formed that penetrates through the gate of a top FET, down to the gate of the bottom FET. To create stacked FETs with merged gates, the process can fill the via with conductive material, thereby electrically connecting the top gate to the bottom gate. To create stacked FETs with separated gates, the process can first line the via with a dielectric material before filling the via with conductive material.

A semiconductor device includes a bottom transistor having a bottom gate. A top transistor has a top gate above the bottom gate and is separated from the bottom transistor by a dielectric layer. A conductive via extends through the top gate and the dielectric layer to contact the bottom transistor. A dielectric liner between the conductive via and the top gate electrically insulates the top gate from the conductive via. The dielectric liner separates the top gate from the bottom gate in a way that minimizes fabrication complexity.

In some cases, a first gate contact extends to the top gate and a second gate contact extends to the conductive via. These separated gate contacts provide an electrical connection to the top gate and to the bottom gate respectively.

In some cases, the top transistor further includes top source/drain structures and the bottom transistor further includes bottom source/drain structures. The semiconductor device may further include source/drain contacts to the top source/drain structures and the bottom source/drain structures. These source/drain structures, and the contacts that connect to them, provide the functionality of the FETs.

In some cases, the conductive via is offset with respect to the top gate. This positioning helps to increase the distance between the conductive via and other conductive structures, such as the source/drain contacts.

In some cases, the dielectric liner is formed from a low-k dielectric material. The use of a low-k dielectric material decreases parasitic capacitances between the top gate and the conductive via.

A semiconductor device includes separated-gate transistors and merged-gate transistors. The separated-gate transistors include a first bottom transistor having a first bottom gate, a first top transistor having a first top gate above the first bottom gate, separated from the first bottom transistor by a dielectric layer, a first conductive via that extends through the top gate and the dielectric layer to contact the bottom transistor, and a dielectric liner between the first conductive via and the first top gate that electrically insulates the first top gate from the first conductive via. The merged-gate transistors include a second bottom transistor having a second bottom gate, a second top transistor having a second top gate above the second bottom gate, separated from the second bottom transistor by the dielectric layer, and a second conductive via that extends through the second top gate and the dielectric layer to contact the second bottom gate, making electrical contact to the second top gate and to the second bottom gate.

In some cases, a first gate contact extends to the first top gate and a second gate contact extends to the first conductive via. These separated gate contacts provide an electrical connection to the top gate and to the bottom gate respectively.

In some cases, the first top transistor and the second top transistor further include respective top source/drain structures and the first bottom transistor and the second bottom transistor further include respective bottom source/drain structures. The semiconductor device may further include source/drain contacts to the top source/drain structures and the bottom source/drain structures. These source/drain structures, and the contacts that connect to them, provide the functionality of the FETs.

In some cases, the first conductive via and the second conductive via are offset with respect to the respective top gates. This positioning helps to increase the distance between the conductive via and other conductive structures, such as the source/drain contacts.

In some cases, the dielectric liner is formed from a low-k dielectric material. The use of a low-k dielectric material decreases parasitic capacitances between the top gate and the conductive via.

In some cases, the second conductive via is in direct contact with the second top gate and the second bottom gate. This merges the second top gate and the second bottom gate.

A method of forming a semiconductor device includes forming a first bottom FET having a first bottom gate. A first top FET having a first top gate is formed over the first bottom gate. A first via is etched through the first top gate to expose the first bottom gate. A dielectric liner is formed in the first via. Conductive material is deposited to fill the first via with conductive material that is electrically insulated from the first top gate by the dielectric liner. The dielectric liner insulates the via from the top gate, so that the via can be placed partially within the top gate, simplifying the fabrication process.

In some cases, a first gate contact to the first top gate is formed and a second gate contact to the conductive material is formed. These separated gate contacts provide an electrical connection to the top gate and to the bottom gate respectively.

In some cases, the method further includes forming a second bottom FET having a second bottom gate, forming a second top FET having a second top gate over the second bottom gate, etching a second via through the second top gate to expose the second bottom gate, masking the second top FET and second via before forming the dielectric liner, and unmasking the second top FET and second via after forming the dielectric liner. In such cases, depositing the conductive material further fills the second via with conductive material that forms an electrical connection between the second top gate and the second bottom gate. Both merged- and separated-gate embodiments can be formed with a single process by the masking.

In some cases, the method further includes forming a first gate contact to the first top gate, forming a second gate contact to the conductive material, and forming a third gate contact to the second top gate. These gate contacts provide respective electrical connections to the top and bottom gates of the separated-gate FETs and to the merged gate of the merged-gate FETs.

In some cases, etching the first via and etching the second via include positioning the respective first and second vias offset with respect to the respective top gates. This positioning helps to increase the distance between the conductive via and other conductive structures, such as the source/drain contacts.

In some cases, etching the first via and etching the second via are performed with a same anisotropic same etch. The separated-gate and merged-gate stacked FETs are formed with the same fabrication processes, so that steps such as the etch of the vias can be shared.

In some cases, depositing the conductive material forms a conductive via in the second via that directly contacts the second top gate and the second bottom gate. The direct contact between these structures enables the merging of the second top gate and the second bottom gate.

In some cases, the first top transistor includes first top source/drain structures and the first bottom transistor includes first bottom source/drain structures. In such cases, the method may further include forming source/drain contacts to the top source/drain structures and the bottom source/drain structures. These source/drain structures, and the contacts that connect to them, provide the functionality of the FETs.

In some cases, the dielectric liner is formed from a low-k dielectric material. The use of a low-k dielectric material decreases parasitic capacitances between the top gate and the conductive via.

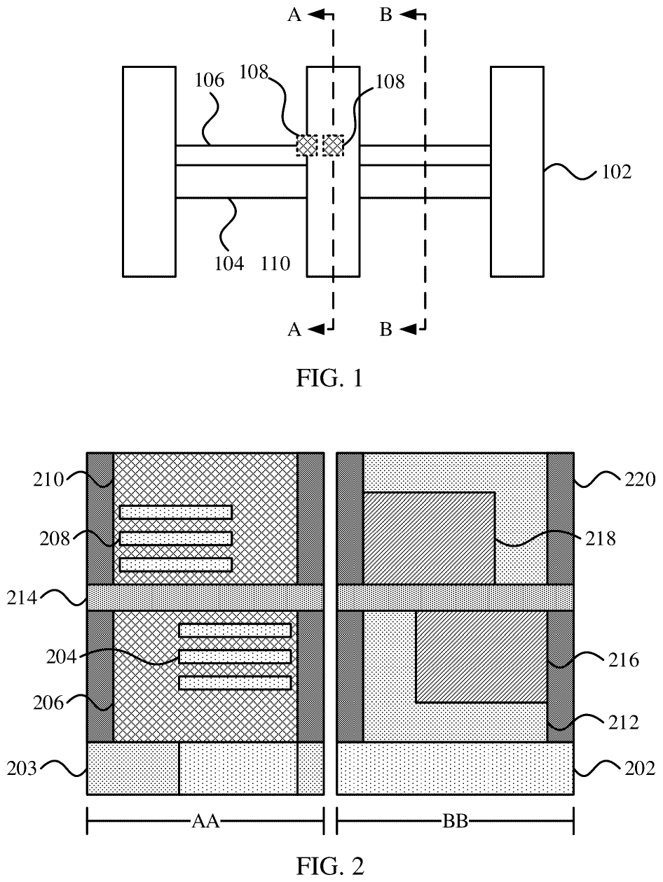

Referring now to FIG. 1, a layout view of a stacked FET semiconductor device is shown. The device includes gates 102 formed over a top channel 104 and a bottom channel 106. This top-down view illustrates that the bottom channel 106 is visible as it extends laterally beyond the edge of the top channel 104. As will be shown in greater detail below, the top channel 104 may similarly extend laterally past the edge of the bottom channel 106. Two cross-sectional planes are shown, including AA, which cuts lengthwise through a gate 102, and BB, which is parallel to AA but which is outside of the gate 102.

A via 108 is shown passing through the gate 102. Two options are shown for the positioning of the via 108, one being centered in the gate 102 and the other being laterally offset. As will be described in greater detail below, this via 108 provides a conductive path to the underlying bottom channel 106. In some cases, the via 108 may be lined with a dielectric to insulate it from the gate 102. In some cases, the via 108 may be unlined, which creates an electrical connection between the gate 102 for the top channel 104 and the bottom channel 106. Positioning the via 108 to one side of the gate 102 makes it possible to create additional space between the via 108 and contacts that reach to source/drain structures.

Referring now to FIG. 2, a set of cross-sectional views is shown of a step in the fabrication of a stacked FET semiconductor device. These views are shown after certain structures have already been formed. In particular, bottom channels 204 and top channels 208 are formed over a semiconductor substrate 202. The semiconductor substrate 202 may have shallow trench isolation (STI) structures 203 in regions around the bottom channels 204. The bottom channels 204 have a bottom gate 206, while the top channels 208 have a top gate 210. The top gate 210 is electrically isolated at this stage from the bottom gate 206 by a dielectric layer 214. Some structures are not shown in this view in the interest of simplicity, such as a top gate dielectric layer on the top channels 208, a bottom gate dielectric layer on the bottom channels 204, and optional work function metal layers. In some cases, the scale of the device may be small enough that the work function metal is used as the gate, without an additional conductive later. The top gate 210 and the bottom gate 206 may be formed from any appropriate conductive material. Gate cut structures 220 are formed from dielectric material through the top channels 208 and the bottom channels 204. In some embodiments the top channels 208 and the bottom channels 204 may make direct contact with respective gate cut structures.

The bottom channels 204 have bottom source/drain structures 216, while the top channels 208 have top source/drain structures 218. The source/drain structures are covered by an interlayer dielectric 212. These structures form complete respective top and bottom FETs, but at this stage lack electrical connections to one another and to other structures in the semiconductor device. The top source/drain structures 218 and the bottom source/drain structures may be doped with any dopant that is appropriate to their associated device type (e.g., p-type or n-type).

The semiconductor substrate 202 may be a bulk-semiconductor substrate. In one example, the bulk-semiconductor substrate may be a silicon-containing material. Illustrative examples of silicon-containing materials suitable for the bulk-semiconductor substrate include, but are not limited to, silicon, silicon germanium, silicon germanium carbide, silicon carbide, polysilicon, epitaxial silicon, amorphous silicon, and multi-layers thereof. Although silicon is the predominantly used semiconductor material in wafer fabrication, alternative semiconductor materials can be employed, such as, but not limited to, germanium, gallium arsenide, gallium nitride, cadmium telluride, and zinc selenide. Although not depicted in the present figures, the semiconductor substrate 202 may also be a semiconductor on insulator (SOI) substrate.

The bottom channels 204 and the top channels 208 may be formed from stacks of semiconductor layers. The stack of semiconductor layers may be formed on the semiconductor substrate 202 by successive epitaxial growth processes. The stack may include channel layers formed from silicon, first sacrificial layers formed from silicon germanium at a first germanium concentration, and second sacrificial layers formed from silicon germanium at a second, higher germanium concentration. The germanium concentrations may be selected to tune etch selectivity. For example, the first sacrificial layers may have a germanium concentration of about 25-30%, while the second sacrificial layers may have a germanium concentration of about 45-60%.

The top FET and the bottom FET may be formed in successive stages. Once the bottom FET has been formed, a second stack of semiconductor layers may be bonded onto the wafer with the bottom FET. The second stack of semiconductor layers can then be processed similarly to form the to FET above the bottom FET.

The terms “epitaxial growth” and “epitaxial deposition” refer to the growth of a semiconductor material on a deposition surface of a semiconductor material, in which the semiconductor material being grown has substantially the same crystalline characteristics as the semiconductor material of the deposition surface. The term “epitaxial material” denotes a material that is formed using epitaxial growth. In some embodiments, when the chemical reactants are controlled and the system parameters set correctly, the depositing atoms arrive at the deposition surface with sufficient energy to move around on the surface and orient themselves to the crystal arrangement of the atoms of the deposition surface. Thus, in some examples, an epitaxial film deposited on a {100} crystal surface will take on a {100} orientation.

A first patterning may be performed to define the bottom channels 204. The patterning may be performed using a photolithographic process. A pattern may be produced by applying a photoresist to the surface to be etched. The photoresist may be exposed to a pattern of radiation. The pattern may then be developed into the photoresist utilizing a resist developer. Once the patterning of the photoresist is completed, the sections covered by the photoresist are protected while the exposed regions are removed using a selective etching process that removes the unprotected regions. In some cases, the photoresist may be used to pattern a hardmask, which in turn is used as a mask for the selective etch.

As used herein, the term “selective” in reference to a material removal process denotes that the rate of material removal for a first material is greater than the rate of removal for at least another material of the structure to which the material removal process is being applied. The second sacrificial layers may selectively be etched away, preserving the channel layers and the first sacrificial layers.

The top channels 208 may be laterally offset with respect to the bottom channels 204. Additional processing may be performed to form dummy gates (not shown), dummy gate spacers (not shown), inner spacers (not shown), source/drain structures (see below), dummy gate removal, and to remove the first sacrificial layers, leaving gaps between the channels using a selective isotropic etch.

In some cases, the top channels 208 and the bottom channels 204 may be formed from a single stack of semiconductor layers. In such cases, the dielectric layer 214 separating the top gate 210 from the bottom gate 206 may be formed by selectively etching away a sacrificial semiconductor layer and replacing the sacrificial semiconductor layer with dielectric material. In some cases, the top channels 208 and the bottom channels 204 may be formed on separate wafers and then bonded together with dielectric layer 214.

An anisotropic etch preferentially removes material in a particular dimension, removing no or little material in other directions. An example of an anisotropic etch is a reactive ion etch (RIE). RIE is a form of plasma etching in which during etching the surface to be etched is placed on a radio-frequency powered electrode. Moreover, during RIE the surface to be etched takes on a potential that accelerates the etching species extracted from plasma toward the surface, in which the chemical etching reaction is taking place in the direction normal to the surface.

The bottom source/drain structures 216 may be epitaxially grown from exposed side surfaces of the bottom channels 204. The top source/drain structures 218 may be epitaxially grown from exposed side surfaces of the top channels 208. These two epitaxial growth processes may perform different respective in situ doping, according to a device type that is being formed. For example, the bottom source/drain structures 216 may be formed with a p-type dopant, while the top source/drain structures 218 may be formed with an n-type dopant (or vice versa). In some cases the bottom source/drain structures 216 and the top source/drain structures may have a same device type and a same dopant.

The deposition processes described herein may include, e.g., chemical vapor deposition (CVD), physical vapor deposition (PVD), atomic layer deposition (ALD), or gas cluster ion beam (GCIB) deposition. CVD is a deposition process in which a deposited species is formed as a result of chemical reaction between gaseous reactants at greater than room temperature (e.g., from about 25° C. about 900° C.). The solid product of the reaction is deposited on the surface on which a film, coating, or layer of the solid product is to be formed. Variations of CVD processes include, but are not limited to, Atmospheric Pressure CVD (APCVD), Low Pressure CVD (LPCVD), Plasma Enhanced CVD (PECVD), and Metal-Organic CVD (MOCVD) and combinations thereof may also be employed. In alternative embodiments that use PVD, a sputtering apparatus may include direct-current diode systems, radio frequency sputtering, magnetron sputtering, or ionized metal plasma sputtering. In alternative embodiments that use ALD, chemical precursors react with the surface of a material one at a time to deposit a thin film on the surface.

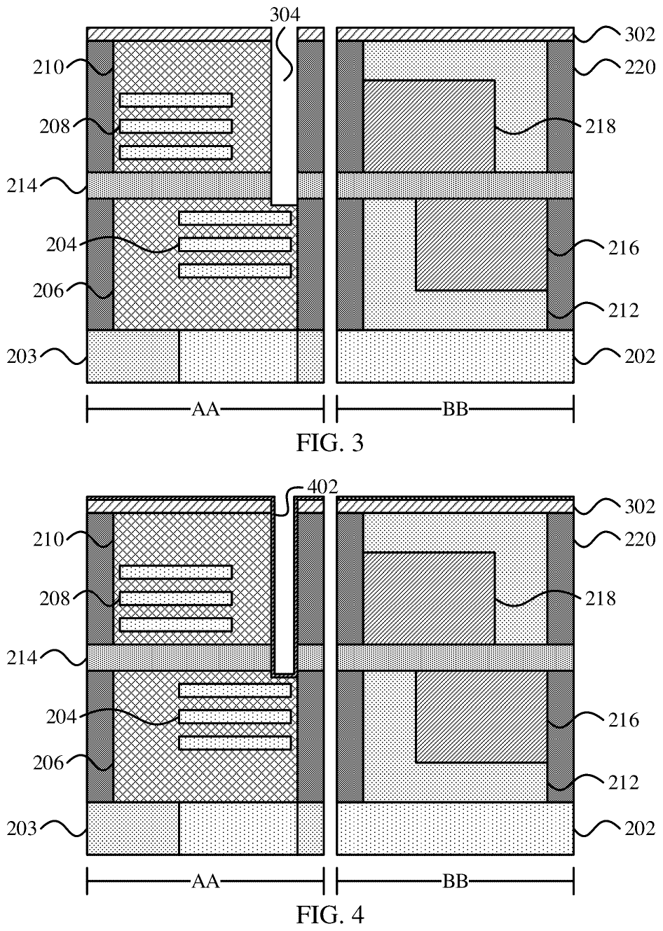

Referring now to FIG. 3, a set of cross-sectional views is shown of a step in the fabrication of a stacked FET semiconductor device. A hardmask 302 is formed using a photolithographic process to define a pattern that is open over the top gate 210, but not over the top channels 208. An anisotropic etch is then performed to open a via 304 through the top gate 210. In some cases, the via 304 cuts through a side surface of the top gate 210. The via 304 further penetrates through the dielectric layer 214 to reach the bottom gate 206. In some embodiments, the via 304 may also cut through the gate cut structures 220.

How the via 304 is processed after this stage determines whether the top gate 210 is electrically merged with the bottom gate 206 or is instead kept electrically separate or isolated. If the via 304 is lined with a dielectric on its sidewalls, the gates will be kept separate and the via 304 provides a contact at the top surface of the device to the bottom gate 206. If the via 304 is filled with a conductor without a dielectric liner, then the top gate 210 will be electrically connected to the bottom gate 206 through the via 304.

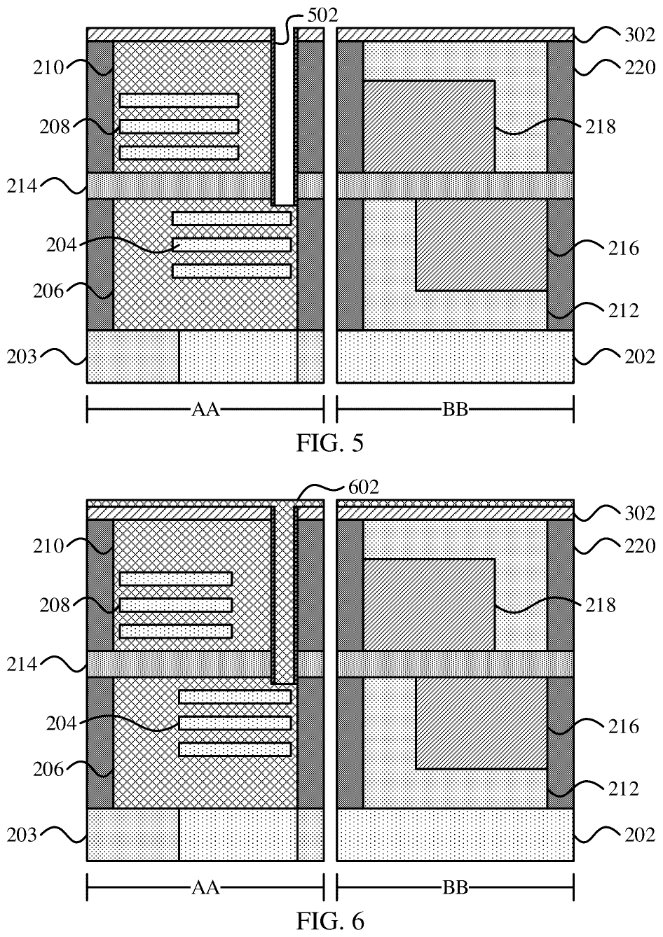

Referring now to FIG. 4, a set of cross-sectional views is shown of a step in the fabrication of a stacked FET semiconductor device. In some embodiments, a dielectric layer 402 may be conformally deposited in the via 304. Any appropriate dielectric material or combination of dielectric materials may be used for the dielectric layer 402, such as SiN or SiBCN or multilayer of dielectrics. Other appropriate materials include low-k dielectric materials.

A low-k dielectric is a material that has a dielectric constant k less than that of silicon dioxide (e.g., about 3.7). Neighboring conductive structures can have capacitive effects, leading to parasitic capacitances in a circuit that can negatively affect performance. The use of a low-k dielectric material to electrically insulate such structures decreases the parasitic capacitance.

Referring now to FIG. 5, a set of cross-sectional views is shown of a step in the fabrication of a stacked FET semiconductor device. A selective anisotropic etch may be performed to remove material from the dielectric layer 402 on horizontal surfaces, leaving the material that is on the vertical inner surfaces of the via 304. This leaves a dielectric liner 502 within the via 304.

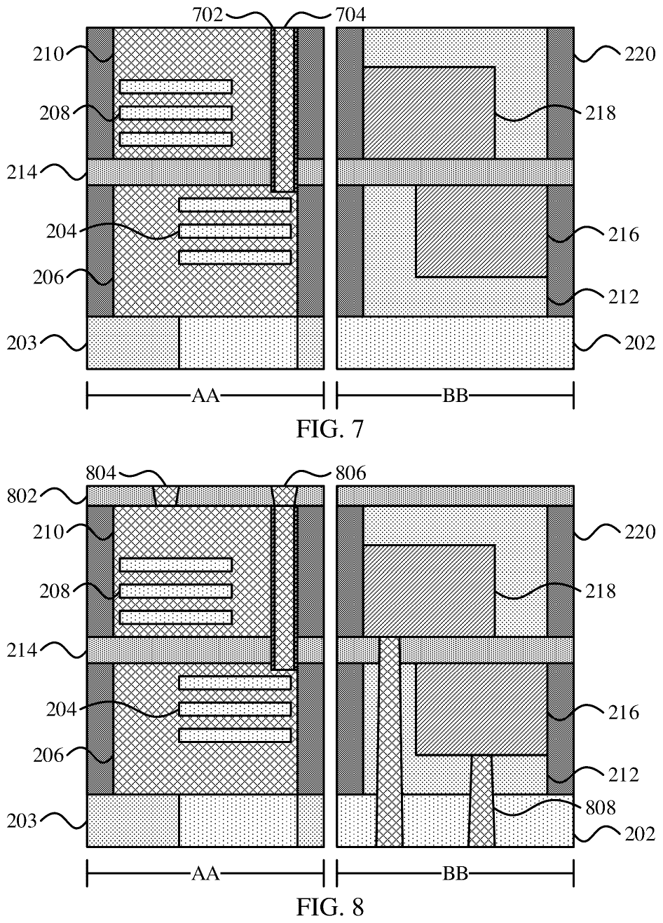

Referring now to FIG. 6, a set of cross-sectional views is shown of a step in the fabrication of a stacked FET semiconductor device. A layer of conductive material 602 is deposited in the via 304 by any appropriate deposition process. The layer of conductive material 602 may be formed from any appropriate conductive metal such as, e.g., tungsten, nickel, titanium, molybdenum, tantalum, copper, platinum, silver, gold, ruthenium, iridium, rhenium, rhodium, cobalt, and alloys or multilayers thereof.

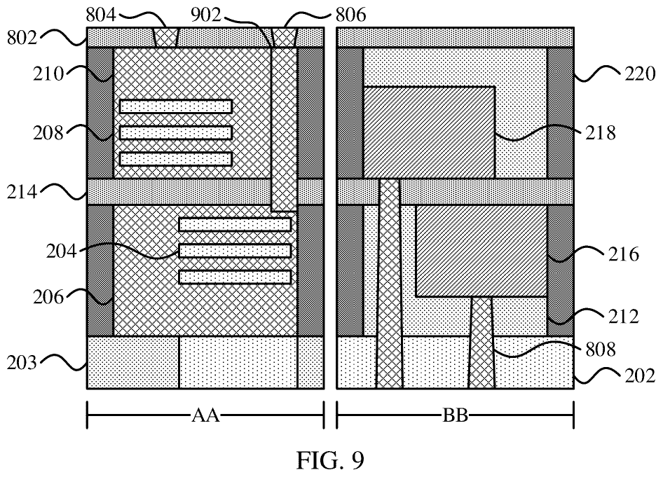

Referring now to FIG. 7, a set of cross-sectional views is shown of a step in the fabrication of a stacked FET semiconductor device. The layer of conductive material 602 and the hardmask 302 are polished down the level of the top gate 210, for example using one or more chemical mechanical planarization (CMP) processes. This leaves dielectric liner 702 and conductive via 704. CMP is performed using, e.g., a chemical or granular slurry and mechanical force to gradually remove upper layers of the device. The slurry may be formulated to be unable to dissolve, for example, the material of the top gate 210, resulting in the CMP process's inability to proceed any farther than that layer. The dielectric liner 702 insulates the conductive via 704 from the top gate 210, providing separate gates with distinct contacts at a top surface.

Referring now to FIG. 8, a set of cross-sectional views is shown of a step in the fabrication of a stacked FET semiconductor device. An interlayer dielectric 802 is formed over the device by any appropriate deposition process, for example using CVD to deposit silicon dioxide. A first gate contact 804 is formed by etching a via through the interlayer dielectric 802 and depositing a conductive material. The first gate contact 804 connects to the top gate 210. A second gate contact 806 is formed by etching a via through the interlayer dielectric 802 and filling with conductive material. The second gate contact 806 connects to the conductive via 704 to provide electrical access to the bottom gate 206.

In some embodiments, source/drain contacts 808 may also be formed to provide electrical access to the top source/drain structure 218 and the bottom source/drain structure 216. The source/drain contacts 808 may be formed from the bottom (as shown) or from the top of the device, penetrating through the interlayer dielectric 212 and the dielectric layer 214 as needed. In some embodiments, the source/drain contacts 808 may be formed from the opposite side of the device as the first gate contact 804 and the second gate contact 806 (as shown) or from the same side of the device. In some embodiments, the source/drain contacts 808 may be formed from the same side of the device as one another (as shown) or from different sides of the device.

Referring now to FIG. 9, a set of cross-sectional views is shown of another embodiment of a stacked FET semiconductor device. This view shows a device that results from the omission of the dielectric liner 702, skipping the steps shown in FIGS. 4 and 5. In such embodiments, the conductive via 902 fully fills the via 304 and makes electrical contact with both the top gate 210 and the bottom gate 206, merging electrically the gates of the top FET and the bottom FET. It should be understood that both embodiments, those with merged gates and those with separate gates, may be formed on a single device by masking merged-gate regions before the formation of the dielectric liner 502. The mask may later be removed, exposing the merged-gate regions, before deposition of the conductive material 602.

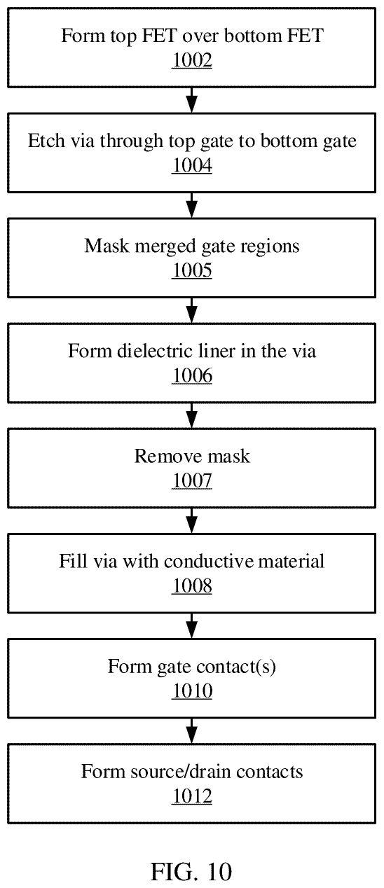

Referring now to FIG. 10, a method of fabricating a stacked FET semiconductor device is shown. Block 1002 forms a top FET over a bottom FET. As described above, this may include forming top channels 208 with top gate 210 and bottom channels 204 with bottom gate 206, separated by a dielectric layer 214. Block 1004 etches a via 304 through the top gate 210, for example by forming a hardmask 302 over the top gate and then using an anisotropic etch. The via extends through the top gate 210 and the dielectric layer 214 to reach the bottom gate 206.

Block 1005 masks regions of the device that will have stacked FETs with merged gates. This may be accomplished by forming a hardmask over the device using a photolithographic process, where the hardmask exposes regions that will have stacked FETs with separate gates. Block 1006 forms a dielectric liner 502 in the via 304 of the exposed regions. Dielectric material may be deposited using a conformal deposition process, such as ALD, and may then be selectively and anisotropically etched back, leaving the dielectric liner 502 on the inner sidewalls of the via 304. Block 1007 may then selectively etch away the mask to expose the regions that will have merged gates.

Block 1008 then fills the via 304 in both the merged-gate regions and the separate-gate regions with a layer of conductive material 602, which may be polished down to the level of the top gate 210 to form conductive vias 704 and 902. Block 1010 forms contacts to the gates, including first gate contacts 804 that contact the top gates 210 and second gate contacts 806 that contact the conductive vias 704/902. Block 1012 forms the source/drain contacts 808 in any appropriate configuration. While the formation of source/drain contacts 808 is described herein as being performed after formation of the gate contacts 804/806, it should be understood that they may instead be formed before forming the gate contacts. In some cases, the formation of the vias may need to etch through a self-aligned contact cap. In some cases, the vias may be formed before a self-aligned contact cap is formed on the top FET.

It is to be understood that aspects of the present invention will be described in terms of a given illustrative architecture; however, other architectures, structures, substrate materials and process features and steps can be varied within the scope of aspects of the present invention.

It will also be understood that when an element such as a layer, region or substrate is referred to as being “on” or “over” another element, it can be directly on the other element or intervening elements can also be present. In contrast, when an element is referred to as being “directly on” or “directly over” another element, there are no intervening elements present. It will also be understood that when an element is referred to as being “connected” or “coupled” to another element, it can be directly connected or coupled to the other element or intervening elements can be present. In contrast, when an element is referred to as being “directly connected” or “directly coupled” to another element, there are no intervening elements present.

The present embodiments can include a design for an integrated circuit chip, which can be created in a graphical computer programming language, and stored in a computer storage medium (such as a disk, tape, physical hard drive, or virtual hard drive such as in a storage access network). If the designer does not fabricate chips or the photolithographic masks used to fabricate chips, the designer can transmit the resulting design by physical means (e.g., by providing a copy of the storage medium storing the design) or electronically (e.g., through the Internet) to such entities, directly or indirectly. The stored design is then converted into the appropriate format (e.g., GDSII) for the fabrication of photolithographic masks, which typically include multiple copies of the chip design in question that are to be formed on a wafer. The photolithographic masks are utilized to define areas of the wafer (and/or the layers thereon) to be etched or otherwise processed.

Methods as described herein can be used in the fabrication of integrated circuit chips. The resulting integrated circuit chips can be distributed by the fabricator in raw wafer form (that is, as a single wafer that has multiple unpackaged chips), as a bare die, or in a packaged form. In the latter case, the chip is mounted in a single chip package (such as a plastic carrier, with leads that are affixed to a motherboard or other higher level carrier) or in a multichip package (such as a ceramic carrier that has either or both surface interconnections or buried interconnections). In any case, the chip is then integrated with other chips, discrete circuit elements, and/or other signal processing devices as part of either (a) an intermediate product, such as a motherboard, or (b) an end product. The end product can be any product that includes integrated circuit chips, ranging from toys and other low-end applications to advanced computer products having a display, a keyboard or other input device, and a central processor.

It should also be understood that material compounds will be described in terms of listed elements, e.g., SiGe. These compounds include different proportions of the elements within the compound, e.g., SiGe includes SiₓGe₁₋ₓ where x is less than or equal to 1, etc. In addition, other elements can be included in the compound and still function in accordance with the present principles. The compounds with additional elements will be referred to herein as alloys.

Reference in the specification to “one embodiment” or “an embodiment”, as well as other variations thereof, means that a particular feature, structure, characteristic, and so forth described in connection with the embodiment is included in at least one embodiment. Thus, the appearances of the phrase “in one embodiment” or “in an embodiment”, as well any other variations, appearing in various places throughout the specification are not necessarily all referring to the same embodiment.

It is to be appreciated that the use of any of the following “/”, “and/or”, and “at least one of”, for example, in the cases of “A/B”, “A and/or B” and “at least one of A and B”, is intended to encompass the selection of the first listed option (A) only, or the selection of the second listed option (B) only, or the selection of both options (A and B). As a further example, in the cases of “A, B, and/or C” and “at least one of A, B, and C”, such phrasing is intended to encompass the selection of the first listed option (A) only, or the selection of the second listed option (B) only, or the selection of the third listed option (C) only, or the selection of the first and the second listed options (A and B) only, or the selection of the first and third listed options (A and C) only, or the selection of the second and third listed options (B and C) only, or the selection of all three options (A and B and C). This can be extended, as readily apparent by one of ordinary skill in this and related arts, for as many items listed.

The terminology used herein is for the purpose of describing particular embodiments only and is not intended to be limiting of example embodiments. As used herein, the singular forms “a,” “an” and “the” are intended to include the plural forms as well, unless the context clearly indicates otherwise. It will be further understood that the terms “comprises,” “comprising,” “includes” and/or “including,” when used herein, specify the presence of stated features, integers, steps, operations, elements and/or components, but do not preclude the presence or addition of one or more other features, integers, steps, operations, elements, components and/or groups thereof.

Spatially relative terms, such as “beneath,” “below,” “lower,” “above,” “upper,” and the like, can be used herein for ease of description to describe one element's or feature's relationship to another element(s) or feature(s) as illustrated in the FIGS. It will be understood that the spatially relative terms are intended to encompass different orientations of the device in use or operation in addition to the orientation depicted in the FIGS. For example, if the device in the FIGS. is turned over, elements described as “below” or “beneath” other elements or features would then be oriented “above” the other elements or features. Thus, the term “below” can encompass both an orientation of above and below. The device can be otherwise oriented (rotated 90 degrees or at other orientations), and the spatially relative descriptors used herein can be interpreted accordingly. In addition, it will also be understood that when a layer is referred to as being “between” two layers, it can be the only layer between the two layers, or one or more intervening layers can also be present.

It will be understood that, although the terms first, second, etc. can be used herein to describe various elements, these elements should not be limited by these terms. These terms are only used to distinguish one element from another element. Thus, a first element discussed below could be termed a second element without departing from the scope of the present concept.

Having described preferred embodiments of selectively merged gates in stacked FETs (which are intended to be illustrative and not limiting), it is noted that modifications and variations can be made by persons skilled in the art in light of the above teachings. It is therefore to be understood that changes may be made in the particular embodiments disclosed which are within the scope of the invention as outlined by the appended claims. Having thus described aspects of the invention, with the details and particularity required by the patent laws, what is claimed and desired protected by Letters Patent is set forth in the appended claims.

1. A semiconductor device, comprising:
a bottom transistor having a bottom gate;
a top transistor having a top gate above the bottom gate, separated from the bottom transistor by a dielectric layer;
a conductive via that extends through the top gate and the dielectric layer to contact the bottom transistor; and
a dielectric liner between the conductive via and the top gate that electrically insulates the top gate from the conductive via.

2. The semiconductor device of claim 1, further comprising a first gate contact to the top gate and a second gate contact to the conductive via.

3. The semiconductor device of claim 1, wherein the top transistor further includes top source/drain structures and the bottom transistor further includes bottom source/drain structures, and wherein the semiconductor device further includes source/drain contacts to the top source/drain structures and the bottom source/drain structures.

4. The semiconductor device of claim 3, wherein the conductive via is offset with respect to the top gate.

5. The semiconductor device of claim 1, wherein the dielectric liner is formed from a low-k dielectric material.

6. A semiconductor device, comprising:
separated-gate transistors, including:
a first bottom transistor having a first bottom gate;
a first top transistor having a first top gate above the first bottom gate, separated from the first bottom transistor by a dielectric layer;
a first conductive via that extends through the top gate and the dielectric layer to contact the first bottom transistor; and
a dielectric liner between the first conductive via and the first top gate that electrically insulates the first top gate from the first conductive via; and
merged-gate transistors, including:
a second bottom transistor having a second bottom gate;
a second top transistor having a second top gate above the second bottom gate, separated from the second bottom transistor by the dielectric layer; and
a second conductive via that extends through the second top gate and the dielectric layer to contact the second bottom gate, making electrical contact to the second top gate and to the second bottom gate.

7. The semiconductor device of claim 6, further comprising a first gate contact to the first top gate and a second gate contact to the first conductive via.

8. The semiconductor device of claim 6, wherein the first top transistor and the second top transistor further include respective top source/drain structures and the first bottom transistor and the second bottom transistor further include respective bottom source/drain structures, and wherein the semiconductor device further includes source/drain contacts to the top source/drain structures and the bottom source/drain structures.

9. The semiconductor device of claim 8, wherein the first conductive via and the second conductive via are partially within the respective top gates and partially within respective gate cut structures.

10. The semiconductor device of claim 6, wherein the dielectric liner is formed from a low-k dielectric material.

11. The semiconductor device of claim 6, wherein the second conductive via is in direct contact with the second top gate and the second bottom gate.

12. A method of forming a semiconductor device, comprising:
forming a first bottom FET having a first bottom gate;
forming a first top FET having a first top gate over the first bottom gate;
etching a first via through the first top gate to expose the first bottom gate;
forming a dielectric liner in the first via; and
depositing a conductive material to fill the first via with the conductive material that is electrically insulated from the first top gate by the dielectric liner.

13. The method of claim 12, further comprising forming a first gate contact to the first top gate and forming a second gate contact to the conductive material.

14. The method of claim 12, further comprising:
forming a second bottom FET having a second bottom gate;
forming a second top FET having a second top gate over the second bottom gate;
etching a second via through the second top gate to expose the second bottom gate;
masking the second top FET and the second via before forming the dielectric liner; and
unmasking the second top FET and the second via after forming the dielectric liner;
wherein depositing the conductive material further fills the second via with the conductive material that forms an electrical connection between the second top gate and the second bottom gate.

15. The method of claim 14, further comprising:
forming a first gate contact to the first top gate;
forming a second gate contact to the conductive material; and
forming a third gate contact to the second top gate.

16. The method of claim 14, wherein etching the first via and etching the second via include positioning the respective first and second vias partially within the respective top gates and partially within respective gate cut structures.

17. The method of claim 14, wherein etching the first via and etching the second via are performed with a same anisotropic same etch.

18. The method of claim 14, wherein depositing the conductive material forms a conductive via in the second via that directly contacts the second top gate and the second bottom gate.

19. The method of claim 12, wherein the first top FET includes first top source/drain structures and the first bottom FET includes first bottom source/drain structures, the method further comprising forming source/drain contacts to the top source/drain structures and the bottom source/drain structures.

20. The method of claim 12, wherein the dielectric liner is formed from a low-k dielectric material.
